(19) United States
(12) Patent Application Publication
(10) Pub. No.: US 2026/0226689 A1
(43) Pub. Date: Aug. 6, 2026

(54) Transport Facility

(71) Applicant: Daifuku Co., Ltd., Osaka-shi (JP)

(72) Inventors: Tomohiko Tsuji, Hinocho (JP); Kenji Ito, Hinocho (JP); Isamu Sasaki, Komaki-shi (TW); Yuichi Morimoto, Komaki-shi (JP)

(21) Appl. No.: 19/530,618

(22) Filed: Feb. 5, 2026

(30) Foreign Application Priority Data
Feb. 6, 2025 (JP) 2025-018256

(51) Int. Cl. E01B 25/24; B61B 3/02

(52) U.S. Cl. CPC E01B 25/24; B61B 3/02

(57) ABSTRACT

A transport facility includes an auxiliary rail including a first auxiliary section in which an auxiliary unit in a transport vehicle comes in contact with and is guided along the auxiliary rail on a second side in a swing direction while a right wheel in the transport vehicle is in a right separation state in which the right wheel is passing through a right separation section, and a second auxiliary section in which the auxiliary unit in the transport vehicle comes in contact with and is guided along the auxiliary rail on a first side in the swing direction while a left wheel in the transport vehicle is in a left separation state in which the left wheel is passing through a left separation section. The right and left separation sections are arranged to cause the right separation state and the left separation state to occur at different times.

### CROSS-REFERENCE TO RELATED APPLICATION

This application claims priority to Japanese Patent Application No. 2025-018256 filed February 6, 2025, the disclosure of which is hereby incorporated by reference in its entirety.

### BACKGROUND OF THE INVENTION

### Field of the Invention

The present invention relates to a transport facility including a transport vehicle and travel rails.

### Description of Related Art

Japanese Unexamined Patent Application Publication No. 2019-186428 (JP 2019-186428) describes a transport facility including a first rail (10) fixed to a first structure (101), a second rail (20) fixed to a second structure (102), and an intermediate rail (30) disposed between these rails.

In the transport facility, pins (52) in a first connection member (50) connecting the first rail (10) and the intermediate rail (30) or pins (62) in a second connection member (60) connecting the second rail (20) and the intermediate rail (30) can break when the first structure (101) and the second structure (102) vibrate differently, causing the intermediate rail (30) to fall on a mount (85) from between the first rail and the second rail.

In the transport facility described in JP 2019-186428, the first connection member or the second connection member in the travel rails can partly break during, for example, an earthquake, causing the intermediate rail to fall. This can cause damage to the intermediate rail or the restoration to take time.

### SUMMARY OF THE INVENTION

Transport facilities including travel rails that are less likely to break when the first structure and the second structure vibrate differently are thus awaited.

A transport facility according to an aspect of the present disclosure includes a transport vehicle and travel rails. The transport vehicle includes a right wheel and a left wheel to travel along a travel path. The travel rails include a right rail on which the right wheel rolls and a left rail on which the left wheel rolls. The travel rails extend across a first structure and a second structure that vibrate differently. The right rail includes a first right rail segment supported by the first structure, and a second right rail segment supported by the second structure and spaced from the first right rail segment in a path direction being a direction parallel to the travel path. The left rail includes a first left rail segment supported by the first structure, and a second left rail segment supported by the second structure and spaced from the first left rail segment in the path direction. The transport vehicle includes an auxiliary unit at a position different from a position of the right wheel and a position of the left wheel. The travel rails include an auxiliary rail in a section of the travel path at a position corresponding to the auxiliary unit. The auxiliary rail includes a first auxiliary section and a second auxiliary section. In the first auxiliary section, the auxiliary unit comes in contact with and is guided along the auxiliary rail on a second side in a swing direction while the right wheel is in a right separation state in which the right wheel is passing through a right separation section. The swing direction is a direction in which the transport vehicle along the travel path swings about a swing axis. The second side in the swing direction is a side on which the left wheel is lowered in the swing direction relative to the right wheel. The right separation section is a section between the first right rail segment and the second right rail segment in the path direction. In the second auxiliary section, the auxiliary unit comes in contact with and is guided along the auxiliary rail on a first side in the swing direction while the left wheel is in a left separation state in which the left wheel is passing through a left separation section. The first side in the swing direction is a side on which the right wheel is lowered in the swing direction relative to the left wheel. The left separation section is a section between the first left rail segment and the second left rail segment in the path direction. The right separation section and the left separation section are arranged to cause the right separation state and the left separation state to occur at different times.

In this structure, each of the right rail and the left rail includes the separation section between the segment supported by the first structure and the segment supported by the second structure. The travel rails are thus less likely to break when the first structure and the second structure vibrate differently. The auxiliary rail includes the first auxiliary section and the second auxiliary section to support the transport vehicle with the auxiliary unit while the right wheel is passing through the right rail separation section or while the left wheel is passing through the left rail separation section. The right rail separation section and the left rail separation section are arranged to cause the right separation state and the left separation state to occur at different times. Thus, the transport vehicle can pass through the separation sections appropriately with the auxiliary unit supporting the transport vehicle in each separation section although the right rail and the left rail each include the separation section.

Further features and advantageous effects of the technique according to one or more embodiments of the present disclosure will be apparent from exemplary and nonlimiting embodiments described below with reference to the drawings.

### BRIEF DESCRIPTION OF THE DRAWINGS

FIG. 1 is a perspective view of a transport facility according to a first embodiment.

FIG. 2 is a front view of the transport facility in FIG. 1.

FIG. 3 is an enlarged side view of a first right rail segment and a third right rail segment included in the transport facility in FIG. 1.

FIG. 4 is a top view of the transport facility in FIG. 1.

FIG. 5 is a diagram of a first swing connection assembly included in the transport facility in FIG. 1, illustrating its function.

FIG. 6 is a top view of a transport facility according to a second embodiment.

FIG. 7 is a bottom view of a transport facility according to a third embodiment.

FIG. 8 is a bottom view of a transport facility according to a fourth embodiment.

### DESCRIPTION OF THE INVENTION

### First Embodiment

A transport facility 10 according to a first embodiment will be described below with reference to the drawings.

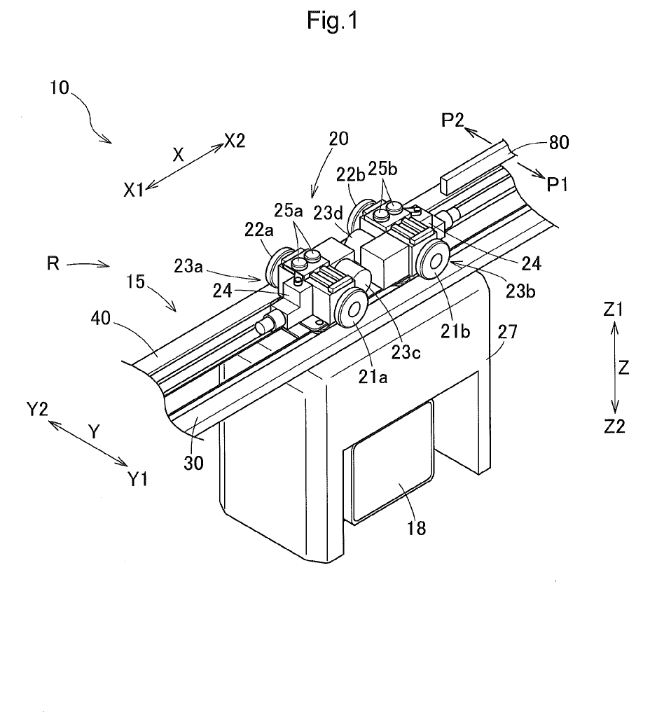

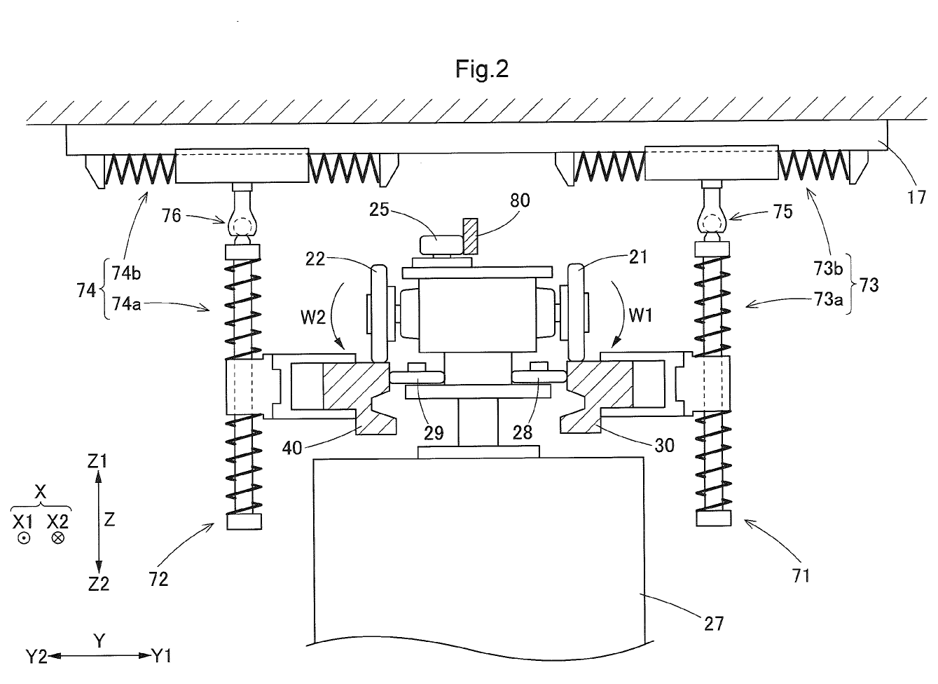

FIG. 1 is a schematic perspective view of an example of the transport facility 10. FIG. 2 is a schematic front view of an example of the transport facility 10. The transport facility 10 includes travel rails 15 and transport vehicles 20. Each transport vehicle 20 travels along a travel path R. The transport vehicle 20 includes right wheels 21 and left wheels 22. The transport vehicle 20 may include two wheels, or three or more wheels.

In the present embodiment, as shown in FIG. 1, the transport vehicle 20 includes a first right wheel 21a, a first left wheel 22a, a second right wheel 21b, and a second left wheel 22b. The first right wheel 21a and the first left wheel 22a rotate about the same rotation axis. The second right wheel 21b and the second left wheel 22b rotate about the same rotation axis.

The travel rails 15 include a right rail 30 on which the right wheels 21 roll and a left rail 40 on which the left wheels 22 roll. In the present embodiment, the travel surfaces on which the right wheels 21 and the left wheels 22 roll are the surfaces of the right rail 30 and left rail 40 facing an upper side Z1. The right wheels 21 and the left wheels 22 rotate about the axes perpendicular to a vertical direction Z. The travel rails 15 are supported by, for example, multiple frames 17 (refer to FIG. 2) installed on the first structure 11 or the second structure 12. In the present embodiment, the travel rails 15 are hung from the ceiling, but the travel rails 15 may be installed on the floor.

The travel rails 15 include an auxiliary rail 80 in at least a part of the travel path R. Although not shown, the auxiliary rail 80 is supported by the travel rails 15.

In the present embodiment, the section of the travel path R including the auxiliary rail 80 is one way.

The direction parallel to the travel path R is referred to as a path direction X. One side in the path direction X is referred to as a first side X1 in the path direction, and the other side in the path direction X is referred to as a second side X2 in the path direction. The second right wheel 21b is disposed on the second side X2 in the path direction relative to the first right wheel 21a. The second left wheel 22b is disposed on the second side X2 in the path direction relative to the first left wheel 22a. In the present embodiment, the transport vehicle 20 travels from the first side X1 in the path direction toward the second side X2 in the path direction.

The direction of gravity is referred to as the vertical direction Z. A direction perpendicular to the path direction X when viewed in the vertical direction is referred to as a lateral direction Y. One side in the lateral direction Y is referred to as a first side Y1 in the lateral direction, and the other side in the lateral direction Y is referred to as a second side Y2 in the lateral direction. A direction in which the transport vehicle 20 along the travel path R swings about a swing axis is referred to as a swing direction W. A side in the swing direction W on which the right wheels 21 are lowered relative to the left wheels 22 is referred to as a first side W1 in the swing direction, and a side in the swing direction W on which the left wheels 22 are lowered relative to the right wheels 21 is referred to as a second side W2 in the swing direction.

The transport vehicle 20 has its swing axis basically at a middle position between the right wheels 21 and the left wheels 22 on the respective axes of the right wheels 21 and the left wheels 22 when+ viewed in the path direction. More specifically, however, the swing axis extends through contact points of the left wheels 22 in a right separation state (described later) or contact points of the right wheels 21 in a left separation state (described later).

In the present embodiment, the transport facility 10 includes multiple transport vehicles 20. In the present embodiment, the transport vehicles 20 are ceiling-hung transport vehicles. In the present embodiment, the transport vehicles 20 are electric automated guided vehicles that transport articles 18. The transport vehicles 20 transport, for example, front-opening unified pods (FOUPs) containing semiconductor substrates as the articles 18.

In the present embodiment, as shown in FIG. 1, each transport vehicle 20 includes a first traveler 23a. The first traveler 23a includes a first travel driver 23c that rotates the first right wheel 21a and the first left wheel 22a. In the present embodiment, each transport vehicle 20 includes a second traveler 23b disposed on the second side X2 in the path direction relative to the first traveler 23a. The second traveler 23b includes a second travel driver 23d that rotates the second right wheel 21b and the second left wheel 22b. Examples of the first travel driver 23c and the second travel driver 23d include electric motors such as servomotors, and combustion engines.

Each transport vehicle 20 includes first auxiliary units 25a. The first auxiliary units 25a come in contact with the guide surface of the auxiliary rail 80. The auxiliary rail 80 has the guide surface on the first side W1 in the swing direction or on the second side W2 in the swing direction of the auxiliary rail 80. In the present embodiment, the guide surface of the auxiliary rail 80 faces either side in the lateral direction Y, and the first auxiliary units 25a rotate about the axes extending in the vertical direction Z. In the present embodiment, the first traveler 23a includes the first auxiliary units 25a.

Two first auxiliary units 25a are aligned in the path direction X.

The transport vehicle 20 includes a guide driver 24 that drives the first auxiliary units 25a to move to a first position P1 relative to the auxiliary rail 80 or a second position P2 relative to the auxiliary rail 80. The first position P1 is on the first side Y1 in the lateral direction. The second position P2 is on the second side Y2 in the lateral direction. Examples of the guide driver 24 include a solenoid actuator, an electric motor, and a hydraulic device.

In the present embodiment, the transport vehicle 20 includes second auxiliary units 25b disposed on the second side X2 in the path direction relative to the first auxiliary units 25a. The second auxiliary units 25b come in contact with the guide surface of the auxiliary rail 80. In the present embodiment, the second traveler 23b includes the second auxiliary units 25b. Two second auxiliary units 25b are aligned in the path direction X. The guide driver 24 drives the first auxiliary units 25a and the second auxiliary units 25b independently of each other in the lateral direction Y.

As shown in FIG. 2, the auxiliary units 25 are at positions different from the positions of the right wheels 21 and the left wheels 22 in the transport vehicle 20. In the present embodiment, the auxiliary units 25 are arranged on the upper side Z1 relative to the rotation axes of the right wheels 21 and the left wheels 22 in the transport vehicle 20. The auxiliary units 25 may be arranged on a side or the bottom of the transport vehicle 20.

The auxiliary rail 80 is disposed at a position corresponding to the auxiliary units 25. In the present embodiment, the auxiliary rail 80 is at a position at which the auxiliary units 25 come in contact with the auxiliary rail 80. In the present embodiment, the auxiliary units 25 are auxiliary wheels that rotate about the rotation axes extending in the vertical direction Z. The auxiliary units 25 may be non-rotatable slide members, and the auxiliary rail 80 may be rollers aligned with one another.

The transport vehicle 20 includes a body 27 coupled to the first traveler 23a. The body 27 is supported by the first traveler 23a on a lower side Z2 in the vertical direction Z relative to the first traveler 23a. In the present embodiment, the body 27 is supported by the first traveler 23a and the second traveler 23b on the lower side Z2 relative to the first traveler 23a and the second traveler 23b. The body 27 includes a lifter (not shown) that raises and lowers an article 18 in the vertical direction Z. The transport vehicle 20 transports an article 18 with the article 18 at a predetermined travel position as shown in, for example, FIG. 1.

As shown in FIG. 2, the transport vehicle 20 includes right guide wheels 28 and left guide wheels 29.

The right guide wheels 28 roll on the inner surface of the right rail 30. The left guide wheels 29 roll on the inner surface of the left rail 40.

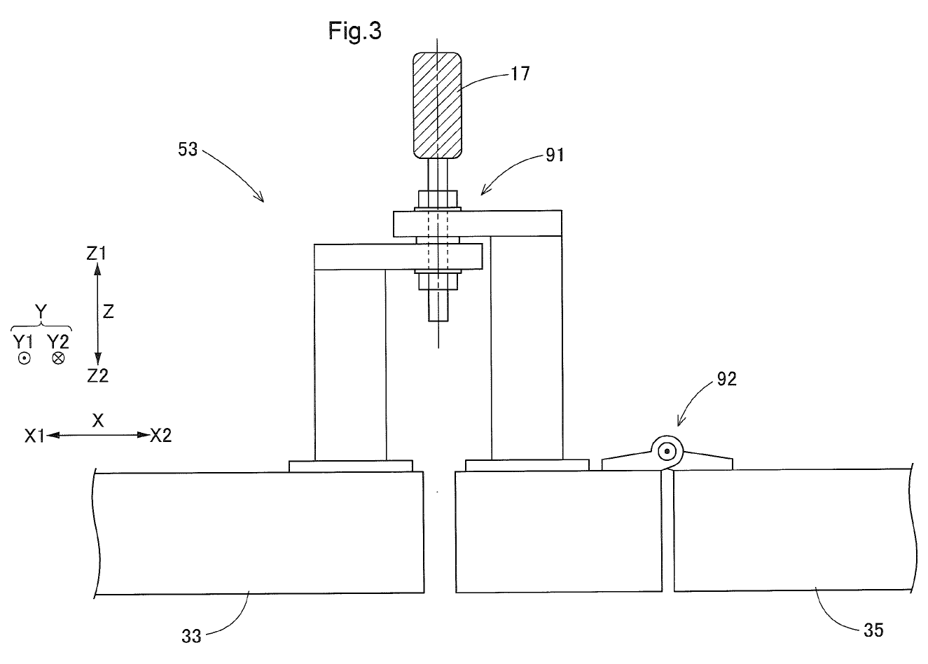

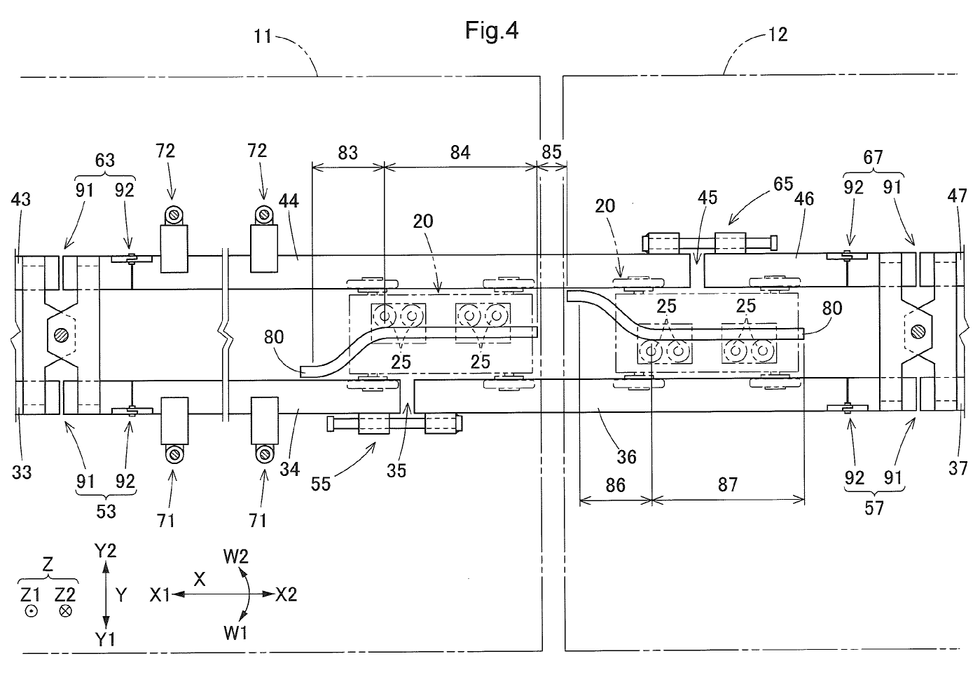

FIG. 3 is a schematic lateral view of a third right rail segment 33 and a first right rail segment 34 in an example. FIG. 4 is a schematic top view of the transport facility 10 in an example.

As shown in FIG. 4, the travel rails 15 extend across the first structure 11 and the second structure 12, which may vibrate differently. In the present embodiment, the first structure 11 and the second structure 12 are different buildings. The first structure 11 and the second structure 12 may be two support frames independent of each other and installed in a single building. The first structure 11 and the second structure 12 may or may not have roofs.

The right rail 30 includes the first right rail segment 34 supported by the first structure 11. The right rail 30 includes a second right rail segment 36 supported by the second structure 12. The second right rail segment 36 is spaced from the first right rail segment 34 in the path direction X.

The left rail 40 includes a first left rail segment 44 supported by the first structure 11. The left rail 40 includes a second left rail segment 46 supported by the second structure 12. The second left rail segment 46 is spaced from the first left rail segment 44 in the path direction X.

The section between the first right rail segment 34 and the second right rail segment 36 in the path direction X is defined as a right separation section 35. The section between the first left rail segment 44 and the second left rail segment 46 in the path direction X is defined as a left separation section 45. In the present embodiment, the right separation section 35 is disposed on the first side X1 in the path direction relative to the left separation section 45.

In the present embodiment, the first right rail segment 34 is disposed on the first side X1 in the path direction relative to the second right rail segment 36. In the present embodiment, the first left rail segment 44 is disposed on the first side X1 in the path direction relative to the second left rail segment 46.

The transport facility 10 includes a right linear guide assembly 55. The right linear guide assembly 55 allows relative movement of the first right rail segment 34 and the second right rail segment 36 in the path direction X. The right linear guide assembly 55 restricts relative movement of the first right rail segment 34 and the second right rail segment 36 in a direction perpendicular to the path direction X.

In the present embodiment, the right linear guide assembly 55 restricts relative movement of the first right rail segment 34 and the second right rail segment 36 in the vertical direction Z. In the present embodiment, the right linear guide assembly 55 restricts relative movement of the first right rail segment 34 and the second right rail segment 36 in the lateral direction Y. Examples of the right linear guide assembly 55 include a ball spline and a linear guide.

The transport facility 10 includes a left linear guide assembly 65. The left linear guide assembly 65 allows relative movement of the first left rail segment 44 and the second left rail segment 46 in the path direction X. The left linear guide assembly 65 restricts relative movement of the first left rail segment 44 and the second left rail segment 46 in a direction perpendicular to the path direction X.

In the present embodiment, the left linear guide assembly 65 restricts relative movement of the first left rail segment 44 and the second left rail segment 46 in the vertical direction Z. In the present embodiment, the left linear guide assembly 65 restricts relative movement of the first left rail segment 44 and the second left rail segment 46 in the lateral direction Y. Examples of the left linear guide assembly 65 include a ball spline and a linear guide.

The right rail 30 includes the third right rail segment 33. The third right rail segment 33 is supported by the first structure 11. The third right rail segment 33 is disposed on the first side X1 in the path direction relative to the first right rail segment 34.

The right rail 30 includes a fourth right rail segment 37. The fourth right rail segment 37 is supported by the second structure 12. The fourth right rail segment 37 is disposed on the second side X2 in the path direction relative to the second right rail segment 36.

The left rail 40 includes a third left rail segment 43. The third left rail segment 43 is supported by the first structure 11. The third left rail segment 43 is disposed on the first side X1 in the path direction relative to the first left rail segment 44.

The left rail 40 includes a fourth left rail segment 47. The fourth left rail segment 47 is supported by the second structure 12. The fourth left rail segment 47 is disposed on the second side X2 in the path direction relative to the second left rail segment 46.

The transport facility 10 includes a right first connection assembly 53. The first right rail segment 34 and the third right rail segment 33 are connected by the right first connection assembly 53 that allows their relative swinging about an axis extending in a direction perpendicular to the path direction X. The first right rail segment 34 and the third right rail segment 33 are supported by the first structure 11 with the right first connection assembly 53.

The transport facility 10 includes a right second connection assembly 57. The second right rail segment 36 and the fourth right rail segment 37 are connected by the right second connection assembly 57 that allows their relative swinging about an axis extending in the direction perpendicular to the path direction X. The second right rail segment 36 and the fourth right rail segment 37 are supported by the second structure 12 with the right second connection assembly 57.

The transport facility 10 includes a left first connection assembly 63. The first left rail segment 44 and the third left rail segment 43 are connected by the left first connection assembly 63 that allows their relative swinging about an axis extending in the direction perpendicular to the path direction X. The first left rail segment 44 and the third left rail segment 43 are supported by the first structure 11 with the left first connection assembly 63.

The transport facility 10 includes a left second connection assembly 67. The second left rail segment 46 and the fourth left rail segment 47 are connected by the left second connection assembly 67 that allows their relative swinging about an axis extending in the direction perpendicular to the path direction X. The second left rail segment 46 and the fourth left rail segment 47 are supported by the second structure 12 with the left second connection assembly 67.

FIG. 3 is a schematic enlarged side view of the right first connection assembly 53 as a typical example of the right first connection assembly 53, the right second connection assembly 57, the left first connection assembly 63, and the left second connection assembly 67. In the present embodiment, the right second connection assembly 57, the left first connection assembly 63, and the left second connection assembly 67 have the same structure as the right first connection assembly 53.

The right first connection assembly 53 includes a first swing connection assembly 91 and a second swing connection assembly 92. The first swing connection assembly 91 allows relative swinging of the first right rail segment 34 and the third right rail segment 33 about an axis extending in a first direction. The second swing connection assembly 92 allows relative swinging of the first right rail segment 34 and the third right rail segment 33 about an axis extending in a second direction. The first direction and the second direction are specific directions perpendicular to the path direction X and different from each other. In the present embodiment, the first direction and the second direction are perpendicular to each other. In the illustrated example, the first direction is the vertical direction Z, and the second direction is the lateral direction Y.

In the present embodiment, the first swing connection assembly 91 in the right first connection assembly 53 and the first swing connection assembly 91 in the left first connection assembly 63 allow the above relative swinging about the same axis extending in the first direction. In the present embodiment, the first swing connection assembly 91 in the right second connection assembly 57 and the first swing connection assembly 91 in the left second connection assembly 67 allow the above relative swinging about the same axis extending in the first direction.

In the present embodiment, the second swing connection assembly 92 in the right first connection assembly 53 and the second swing connection assembly 92 in the left first connection assembly 63 allow the above relative swinging about the same axis extending in the second direction. In the present embodiment, the second swing connection assembly 92 in the right second connection assembly 57 and the second swing connection assembly 92 in the left second connection assembly 67 allow the above relative swinging about the same axis extending in the second direction.

As shown in FIGS. 2 and 4, the transport facility 10 includes first right support assemblies 71 supported by the first structure 11. The first right support assemblies 71 support the first right rail segment 34 to allow movement of the first right rail segment 34 in the vertical direction Z relative to the first structure 11. The first right support assemblies 71 support the first right rail segment 34 to allow movement of the first right rail segment 34 in the lateral direction Y relative to the first structure 11.

The first right support assemblies 71 support the first right rail segment 34 to allow movement of the first right rail segment 34 in the path direction X relative to the first structure 11. Each first right support assembly 71 includes, for example, a linear guide or a ball spline to allow movement of the first right rail segment 34.

As shown in FIGS. 2 and 4, the transport facility 10 includes first left support assemblies 72 supported by the first structure 11. The first left support assemblies 72 support the first left rail segment 44 to allow movement of the first left rail segment 44 in the vertical direction Z relative to the first structure 11. The first left support assemblies 72 support the first left rail segment 44 to allow movement of the first left rail segment 44 in the lateral direction Y relative to the first structure 11.

The first left support assemblies 72 support the first right rail segment 34 to allow movement of the first right rail segment 34 in the path direction X relative to the first structure 11. Each first left support assembly 72 includes, for example, a linear guide or a ball spline to allow movement of the first left rail segment 44.

As shown in FIG. 2, each first right support assembly 71 includes a first urging assembly 73a that urges the first right rail segment 34 toward a reference position in the vertical direction Z. Each first right support assembly 71 includes a first urging assembly 73b that urges the first right rail segment 34 toward a reference position in the lateral direction Y. The first urging assembly 73b includes, for example, a coil spring, a leaf spring, or a spring using a magnetic force or an atmospheric pressure to urge the first right rail segment 34 toward the reference position.

As shown in FIG. 2, each first left support assembly 72 includes a second urging assembly 74a that urges the first right rail segment 34 toward a reference position in the vertical direction Z. Each first left support assembly 72 includes a second urging assembly 74b that urges the first right rail segment 34 toward a reference position in the lateral direction Y. The second urging assembly 74b includes, for example, a coil spring, a leaf spring, or a spring using a magnetic force or an atmospheric pressure to urge the first right rail segment 34 toward the reference position.

Each first right support assembly 71 includes a first joint 75 swingable about one or more axes.

In the present embodiment, the first joint 75 is swingable about three axes. Each first left support assembly 72 includes a second joint 76 swingable about one or more axes. In the present embodiment, the second joint 76 is swingable about three axes. Examples of the first joint 75 and the second joint 76 include a ball joint, an elliptical joint, a saddle joint, a hinge joint, and a pivot joint.

As shown in FIG. 4, the auxiliary rail 80 includes a first auxiliary section 84. In the first auxiliary section 84, the auxiliary units 25 come in contact with and are guided along the auxiliary rail 80 on the second side W2 in the swing direction while the right wheels 21 are in the right separation state in which the right wheels 21 are passing through the right separation section 35. In the first auxiliary section 84 in the present embodiment, the auxiliary units 25, which are auxiliary wheels, in the right separation state come in contact with and roll on the auxiliary rail 80 on the second side W2 in the swing direction. In the present embodiment, the section of the travel path R including the first auxiliary section 84 is one way.

The transport vehicle 20 is supported by at least the auxiliary units 25 and the left wheels 22 in the right separation state. In the present embodiment, the transport vehicle 20 is supported by the auxiliary units 25, the left wheels 22, and the left guide wheels 29 in the right separation state.

The transport vehicle 20 is supported by at least the auxiliary units 25 and the right wheels 21 in the left separation state. In the present embodiment, the transport vehicle 20 is supported by the auxiliary units 25, the right wheels 21, and the right guide wheels 28 in the left separation state.

As shown in FIG. 4, the auxiliary rail 80 includes a second auxiliary section 87. In the second auxiliary section 87, the auxiliary units 25 come in contact with and are guided along the auxiliary rail 80 on the first side W1 in the swing direction while the left wheels 22 are in the left separation state in which the left wheels 22 are passing through the left separation section 45. In the second auxiliary section 87 in the present embodiment, the auxiliary units 25, which are auxiliary wheels, in the left separation state come in contact with and roll on the auxiliary rail 80 on the first side W1 in the swing direction. In the present embodiment, the section of the travel path R including the second auxiliary section 87 is one way.

In the present embodiment, the right separation section 35 and the left separation section 45 are arranged to cause the right separation state and the left separation state to occur at different times. In the present embodiment, the distance between the right separation section 35 and the left separation section 45 is different from the distance between the first right wheel 21a and the second right wheel 21b. In the present embodiment, the distance between the right separation section 35 and the left separation section 45 is different from the distance between the first left wheel 22a and the second left wheel 22b. Thus, the right separation state and the left separation state do not occur simultaneously.

In the present embodiment, the first auxiliary section 84 and the second auxiliary section 87 overlap each other when viewed in the path direction X. An auxiliary rail separation section 85 being free of the auxiliary rail 80 is defined between the first auxiliary section 84 and the second auxiliary section 87. The auxiliary rail separation section 85 overlaps both the first structure 11 and the second structure 12 when viewed in the vertical direction.

The auxiliary rail 80 includes a first slope section 83. The first slope section 83 is continuous with the first auxiliary section 84. The first slope section 83 slopes toward the second side W2 in the swing direction at positions closer to the first auxiliary section 84. In the present embodiment, the section of the travel path R including the first slope section 83 is one way.

The auxiliary rail 80 includes a second slope section 86. The second slope section 86 is continuous with the second auxiliary section 87. The second slope section 86 slopes toward the first side W1 in the swing direction at positions closer to the second auxiliary section 87. In the present embodiment, the section of the travel path R including the second slope section 86 is one way.

The first slope section 83 is continuous with the first auxiliary section 84 on a side opposite to the auxiliary rail separation section 85 in the path direction X relative to the first auxiliary section 84. The first slope section 83 slopes toward the second side W2 in the swing direction at positions closer to the auxiliary rail separation section 85.

The second slope section 86 is continuous with the second auxiliary section 87 on a side toward the auxiliary rail separation section 85 in the path direction X. The second slope section 86 slopes toward the second side W2 in the swing direction at positions closer to the auxiliary rail separation section 85.

In the first slope section 83, the auxiliary units 25 come in contact with and are guided along the auxiliary rail 80 on the second side W2 in the swing direction. In the first slope section 83 in the present embodiment, the auxiliary units 25 as the auxiliary wheels come in contact with and roll on the auxiliary rail 80 on the second side W2 in the swing direction.

In the second slope section 86, the auxiliary units 25 come in contact with and are guided along the auxiliary rail 80 on the first side W1 in the swing direction. In the second slope section 86 in the present embodiment, the auxiliary units 25 as the auxiliary wheels come in contact with and roll on the auxiliary rail 80 on the first side W1 in the swing direction.

In the present embodiment, the first slope section 83 allows the auxiliary units 25 to move from the first position P1 to the second position P2. In the present embodiment, the position change of the auxiliary units 25 from the first position P1 to the second position P2 is forcibly performed by the first slope section 83, rather than by the guide driver 24. In the present embodiment, the first auxiliary section 84 causes the auxiliary units 25 at the second position P2 to come in contact with the auxiliary rail 80 on the first side W1 in the swing direction.

In the present embodiment, the second slope section 86 allows the auxiliary units 25 to move from the second position P2 to the first position P1. In the present embodiment, the position change of the auxiliary units 25 from the second position P2 to the first position P1 is forcibly performed by the second slope section 86, rather than by the guide driver 24. In the present embodiment, the second auxiliary section 87 causes the auxiliary units 25 at the first position P1 to come in contact with the auxiliary rail 80 on the second side W2 in the swing direction.

The auxiliary rail 80 is supported by the first structure 11 or the second structure 12, or includes a section supported by the first structure 11 and a section supported by the second structure 12 separated from each other. In the present embodiment, the auxiliary rail 80 includes a section supported by the first structure 11 and a section supported by the second structure 12 separated from each other.

In the present embodiment, the first slope section 83 and the first auxiliary section 84 are supported by the first structure 11 with the first left rail segment 44. In the present embodiment, the second slope section 86 and the second auxiliary section 87 are supported by the second structure 12 with the second right rail segment 36.

The transport facility 10 according to the present embodiment includes the first auxiliary section 84 and the second auxiliary section 87. This structure allows the right separation section 35 and the left separation section 45 to be relatively long, and reduces the likelihood that the travel rails 15 break when the first structure 11 and the second structure 12 vibrate differently.

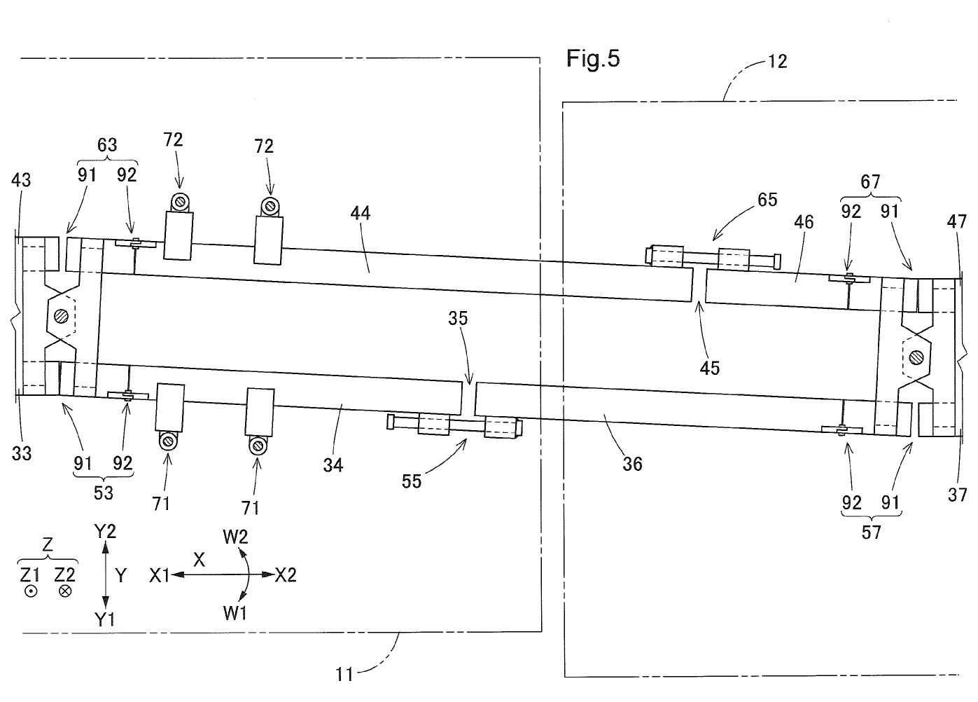

FIG. 5 is a schematic diagram of the right first connection assembly 53, the right second connection assembly 57, the left first connection assembly 63, and the left second connection assembly 67, showing their example functions. In the state shown in FIG. 5, the fourth right rail segment 37 and the fourth left rail segment 47 supported by the second structure 12 are displaced to the first side Y1 in the lateral direction relative to the third right rail segment 33 and the third left rail segment 43 supported by the first structure 11. This may occur, for example, when the first structure 11 and the second structure 12 vibrate differently, or when the ground on which the first structure 11 is built and the ground on which the second structure 12 is built are displaced.

In the present embodiment, the transport facility 10 includes the right first connection assembly 53, the right second connection assembly 57, the left first connection assembly 63, and the left second connection assembly 67. This structure can thus reduce the likelihood of breakage of the rails although the first right rail segment 34 and the second right rail segment 36 are coupled by the right linear guide assembly 55 and the first left rail segment 44 and the second left rail segment 46 are coupled by the left linear guide assembly 65.

In the present embodiment, the transport facility 10 includes the first right support assemblies 71 and the first left support assemblies 72. This structure can thus reduce the likelihood of breakage of the first right rail segment 34 and the first left rail segment 44 being relatively long.

### Second Embodiment

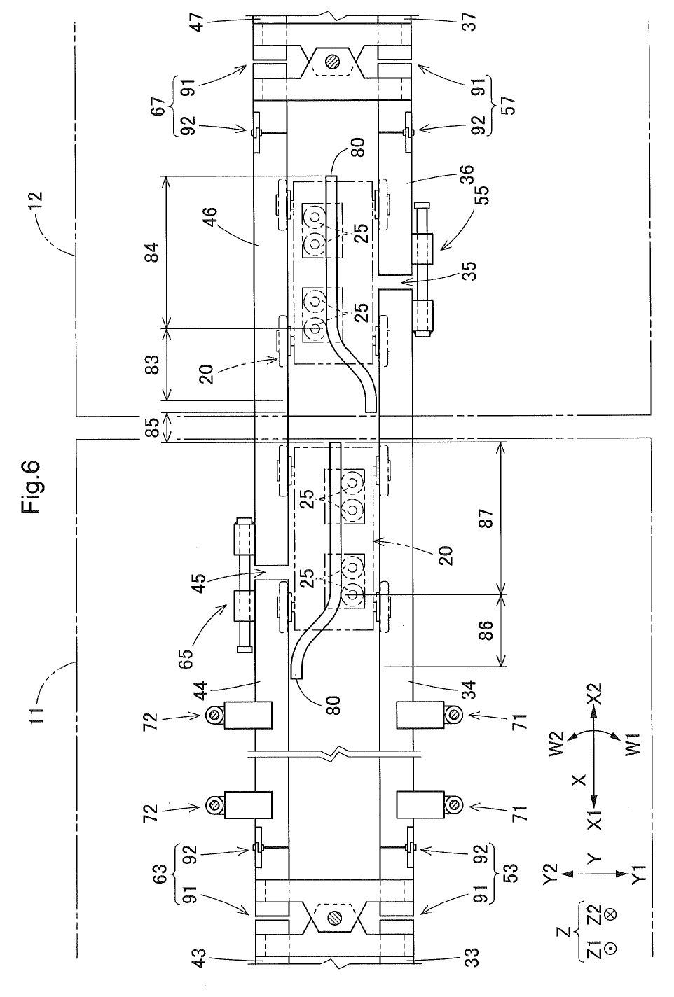

A transport facility 10 according to a second embodiment will now be described with reference to the drawings. The present embodiment differs from the first embodiment in that the right separation section 35 is disposed on the second side X2 in the path direction relative to the left separation section 45. The differences from the first embodiment will mainly be described below. The components and the structures not described below are the same as those in the first embodiment. FIG. 6 is a top view of the transport facility 10 according to the present embodiment.

In the present embodiment, the first slope section 83 is continuous with the first auxiliary section 84 on a side toward the auxiliary rail separation section 85 in the path direction X. The first slope section 83 slopes toward the first side W1 in the swing direction at positions closer to the auxiliary rail separation section 85.

In the present embodiment, the second slope section 86 is continuous with the second auxiliary section 87 on a side opposite to the auxiliary rail separation section 85 in the path direction X. The second slope section 86 slopes toward the first side W1 in the swing direction at positions closer to the auxiliary rail separation section 85.

In the present embodiment, the first auxiliary section 84 and the first slope section 83 are supported by the second structure 12 with the second left rail segment 46. In the present embodiment, the second auxiliary section 87 and the second slope section 86 are supported by the first structure 11 with the first right rail segment 34.

### Third Embodiment

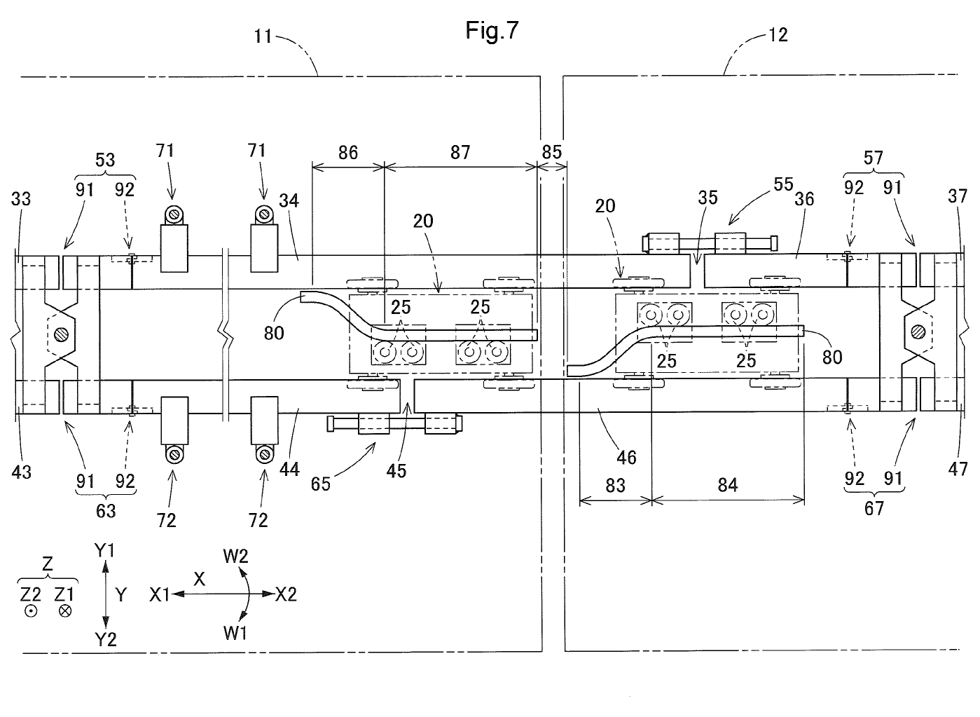

A transport facility 10 according to a third embodiment will now be described with reference to the drawings. The present embodiment differs from the first embodiment in that the right separation section 35 is disposed on the second side X2 in the path direction relative to the left separation section 45, and the auxiliary rail 80 is disposed on the lower side Z2 relative to the rotational axes of the right wheels 21 and the left wheels 22. The differences from the first embodiment will mainly be described below. The components and the structures not described below are the same as those in the first embodiment. FIG. 7 is a bottom view of the transport facility 10 according to the present embodiment.

In the present embodiment, the auxiliary units 25 are disposed on the lower side Z2 relative to the rotation axes of the right wheels 21 and the left wheels 22 in the transport vehicle 20.

In the present embodiment, the first slope section 83 is continuous with the first auxiliary section 84 on a side toward the auxiliary rail separation section 85 in the path direction X. The first slope section 83 slopes toward the first side W1 in the swing direction at positions closer to the auxiliary rail separation section 85.

In the present embodiment, the second slope section 86 is continuous with the second auxiliary section 87 on a side opposite to the auxiliary rail separation section 85 in the path direction X. The second slope section 86 slopes toward the first side W1 in the swing direction at positions closer to the auxiliary rail separation section 85.

In the present embodiment, the first slope section 83 allows the auxiliary units 25 to move from the second position P2 on the second side Y2 in the lateral direction to the first position P1 on the first side Y1 in the lateral direction. In the present embodiment, the first auxiliary section 84 causes the auxiliary units 25 at the first position P1 to come in contact with the auxiliary rail 80 on the first side W1 in the swing direction.

In the present embodiment, the second slope section 86 allows the auxiliary units 25 to move from the first position P1 on the first side Y1 in the lateral direction to the second position P2 on the second side Y2 in the lateral direction. In the present embodiment, the second auxiliary section 87 causes the auxiliary units 25 at the second position P2 to come in contact with the auxiliary rail 80 on the second side W2 in the swing direction.

In the present embodiment, the first auxiliary section 84 and the first slope section 83 are supported by the second structure 12 with the second left rail segment 46. In the present embodiment, the second auxiliary section 87 and the second slope section 86 are supported by the first structure 11 with the first right rail segment 34.

### Fourth Embodiment

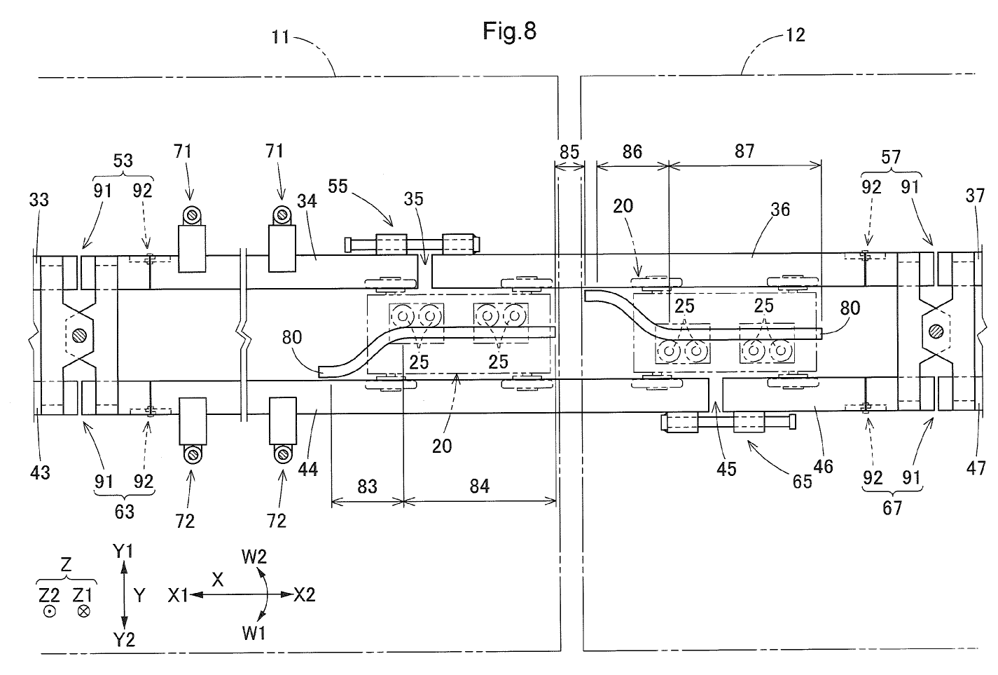

A transport facility 10 according to a fourth embodiment will now be described with reference to the drawings. The present embodiment differs from the third embodiment in that the left separation section 45 is disposed on the second side X2 in the path direction relative to the right separation section 35. The differences from the third embodiment will mainly be described below. The components and the structures not described below are the same as those in the third embodiment. FIG. 8 is a bottom view of the transport facility 10 according to the present embodiment.

In the present embodiment, the first slope section 83 is continuous with the first auxiliary section 84 on a side opposite to the auxiliary rail separation section 85 in the path direction X. The first slope section 83 slopes toward the second side W2 in the swing direction at positions closer to the auxiliary rail separation section 85.

In the present embodiment, the second slope section 86 is continuous with the second auxiliary section 87 on a side toward the auxiliary rail separation section 85 in the path direction X. The second slope section 86 slopes toward the second side W2 in the swing direction at positions closer to the auxiliary rail separation section 85.

In the present embodiment, the first slope section 83 allows the auxiliary units 25 to move from the first position P1 on the first side Y1 in the lateral direction to the second position P2 on the second side Y2 in the lateral direction. In the present embodiment, the first auxiliary section 84 causes the auxiliary units 25 at the second position P2 to come in contact with the auxiliary rail 80 on the first side W1 in the swing direction.

In the present embodiment, the second slope section 86 allows the auxiliary units 25 to move from the second position P2 on the second side Y2 in the lateral direction to the first position P1 on the first side Y1 in the lateral direction. In the present embodiment, the second auxiliary section 87 causes the auxiliary units 25 at the first position P1 to come in contact with the auxiliary rail 80 on the second side W2 in the swing direction.

In the present embodiment, the first auxiliary section 84 and the first slope section 83 are supported by the first structure 11 with the first left rail segment 44. In the present embodiment, the second auxiliary section 87 and the second slope section 86 are supported by the second structure 12 with the second right rail segment 36.

### Other Embodiments

A transport facility 10 according to other embodiments will now be described.

(1) In the above embodiments, the guide driver 24 drives the auxiliary units 25 to move between the first position P1 and the second position P2. However, the transport facility 10 according to one or more embodiments may have another structure. For example, the transport vehicle 20 may not include the guide driver 24, and the auxiliary units 25 may be fixed to the body of the transport vehicle 20.

(2) In the above embodiments, the first slope section 83 and the first auxiliary section 84 are supported by the first structure 11 with the first left rail segment 44, and the second slope section 86 and the second auxiliary section 87 are supported by the second structure 12 with the second right rail segment 36 (refer to FIGS. 4 and 8). However, the transport facility 10 according to one or more embodiments may have another structure. For example, the first slope section 83 and the first auxiliary section 84 may be supported by the second structure 12 without using the right rail 30 and the left rail 40. For example, the second slope section 86 and the second auxiliary section 87 may be supported by the first structure 11 without using the right rail 30 and the left rail 40. For example, the first auxiliary section 84, the first slope section 83, the second slope section 86, and the second auxiliary section 87 may be entirely supported by the first structure 11 or the second structure 12. For example, the auxiliary rail 80 may be supported by a structure different from the first structure 11 and the second structure 12.

(3) In the above embodiments, the transport facility 10 includes the right first connection assembly 53, the right linear guide assembly 55, the right second connection assembly 57, the left first connection assembly 63, the left linear guide assembly 65, and the left second connection assembly 67. However, the transport facility 10 according to one or more embodiments may have another structure. For example, the transport facility 10 may not include one or more of the right first connection assembly 53, the right linear guide assembly 55, the right second connection assembly 57, the left first connection assembly 63, the left linear guide assembly 65, and the left second connection assembly 67.

(4) In the above embodiments, the right rail 30 includes the third right rail segment 33 and the fourth right rail segment 37, and the left rail 40 includes the third left rail segment 43 and the fourth left rail segment 47. However, the transport facility 10 according to one or more embodiments may have another structure. For example, the right rail 30 may not include one or both of the third right rail segment 33 and the fourth right rail segment 37. For example, the left rail 40 may not include one or both of the third left rail segment 43 and the fourth left rail segment 47.

(5) In the above embodiments, the auxiliary rail separation section 85 is defined between the first auxiliary section 84 and the second auxiliary section 87, and the auxiliary rail 80 includes the first slope section 83 and the second slope section 86. However, the transport facility 10 according to one or more embodiments may have another structure. For example, the auxiliary rail separation section 85 may not be defined between the first auxiliary section 84 and the second auxiliary section 87. For example, the auxiliary rail 80 may not include the first slope section 83 or the second slope section 86.

(6) In the above embodiments, the first right support assemblies 71 and the first left support assemblies 72 allow movement in the vertical direction Z, movement in the lateral direction Y, and movement in the path direction X.

However, the transport facility 10 according to one or more embodiments may have another structure. For example, the first right support assemblies 71 and the first left support assemblies 72 may not allow movement in one or more of the vertical direction Z, the lateral direction Y, and the path direction X. For example, each first right support assembly 71 may not include one or both of the first urging assembly 73a and the first urging assembly 73b. For example, each first left support assembly 72 may not include one or both of the second urging assembly 74a and the second urging assembly 74b.

(7) In the above embodiments, the transport facility 10 includes the first right support assemblies 71 and the first left support assemblies 72. However, the transport facility 10 according to one or more embodiments may have another structure. For example, the transport facility 10 may not include the first right support assemblies 71 and the first left support assemblies 72. The first right rail segment 34 and the first left rail segment 44 may be fixed to the first structure 11 not to allow all the movement of the first right rail segment 34 and the first left rail segment 44 in the vertical direction Z, the lateral direction Y, and the path direction X relative to the first structure 11. For example, second right support assemblies (not shown) having the same structure as the first right support assemblies 71 may support the second right rail segment 36 and be supported by the second structure 12. For example, second left support assemblies (not shown) having the same structure as the first left support assemblies 72 may support the second left rail segment 46 and be supported by the second structure 12.

(8) In the above embodiments, the auxiliary units 25 are auxiliary wheels. The auxiliary units 25 are disposed on the upper side Z1 or the lower side Z2 relative to the rotation axes of the right wheels 21 and the left wheels 22 in the transport vehicle 20. However, the transport facility 10 according to one or more embodiments may have another structure. For example, the pair of auxiliary units 25 may be separately arranged in the lateral direction Y and overlap the rotation axes of the right wheels 21 and the left wheels 22.

(9) In the above embodiments, the first right rail segment 34 is disposed on the first side X1 in the path direction relative to the second right rail segment 36, the first left rail segment 44 is disposed on the first side X1 in the path direction relative to the second left rail segment 46, and the transport vehicle 20 travels from the first side X1 in the path direction toward the second side X2 in the path direction. However, the transport facility 10 according to one or more embodiments may have another structure. For example, the transport vehicle 20 may travel from the second side X2 in the path direction toward the first side X1 in the path direction. For example, the section of the travel path R including the auxiliary rail 80 may not be one way.

(10) The structure described in each of the above embodiments may be combined with any other structures described in the other embodiments unless any contradiction arises. For other structures as well, the embodiments described herein are mere examples in all aspects. The embodiments may thus be modified variously as appropriate without departing from the spirit and scope of the present disclosure.

The transport facility according to one or more embodiments of the present disclosure will be described below.

A transport facility according to one aspect includes a transport vehicle and travel rails. The transport vehicle includes a right wheel and a left wheel to travel along a travel path. The travel rails include a right rail on which the right wheel rolls and a left rail on which the left wheel rolls. The travel rails extend across a first structure and a second structure that vibrate differently. The right rail includes a first right rail segment supported by the first structure, and a second right rail segment supported by the second structure and spaced from the first right rail segment in a path direction being a direction parallel to the travel path. The left rail includes a first left rail segment supported by the first structure, and a second left rail segment supported by the second structure and spaced from the first left rail segment in the path direction. The transport vehicle includes an auxiliary unit at a position different from a position of the right wheel and a position of the left wheel. The travel rails include an auxiliary rail in a section of the travel path at a position corresponding to the auxiliary unit. The auxiliary rail includes a first auxiliary section and a second auxiliary section. In the first auxiliary section, the auxiliary unit comes in contact with and is guided along the auxiliary rail on a second side in a swing direction while the right wheel is in a right separation state in which the right wheel is passing through a right separation section. The swing direction is a direction in which the transport vehicle along the travel path swings about a swing axis. The second side in the swing direction is a side on which the left wheel is lowered in the swing direction relative to the right wheel. The right separation section is a section between the first right rail segment and the second right rail segment in the path direction. In the second auxiliary section, the auxiliary unit comes in contact with and is guided along the auxiliary rail on a first side in the swing direction while the left wheel is in a left separation state in which the left wheel is passing through a left separation section. The first side in the swing direction is a side on which the right wheel is lowered in the swing direction relative to the left wheel. The left separation section is a section between the first left rail segment and the second left rail segment in the path direction. The right separation section and the left separation section are arranged to cause the right separation state and the left separation state to occur at different times.

In this structure, each of the right rail and the left rail includes the separation section between the segment supported by the first structure and the segment supported by the second structure. The travel rails are thus less likely to break when the first structure and the second structure vibrate differently. The auxiliary rail includes the first auxiliary section and the second auxiliary section to support the transport vehicle with the auxiliary unit while the right wheel is passing through the right rail separation section or while the left wheel is passing through the left rail separation section. The right rail separation section and the left rail separation section are arranged to cause the right separation state and the left separation state to occur at different times. Thus, the transport vehicle can pass through the separation sections appropriately with the auxiliary unit supporting the transport vehicle in each separation section.

In one aspect, the auxiliary rail is supported by the first structure or the second structure, or the auxiliary rail includes a section supported by the first structure and a section supported by the second structure separated from each other.

In this structure, the auxiliary rail is less likely to break when the first structure and the second structure vibrate differently.

In one aspect, the transport facility further includes a right linear guide assembly and a left linear guide assembly. The right linear guide assembly allows relative movement of the first right rail segment and the second right rail segment in the path direction and restricts relative movement of the first right rail segment and the second right rail segment in a direction perpendicular to the path direction. The left linear guide assembly allows relative movement of the first left rail segment and the second left rail segment in the path direction and restricts relative movement of the first left rail segment and the second left rail segment in the direction perpendicular to the path direction. The right rail has the first right rail segment disposed on a first side in the path direction relative to the second right rail segment. The right rail includes a third right rail segment and a fourth right rail segment. The third right rail segment is supported by the first structure and disposed on the first side in the path direction relative to the first right rail segment. The fourth right rail segment is supported by the second structure and disposed on a second side in the path direction relative to the second right rail segment. The left rail has the first left rail segment disposed on the first side in the path direction relative to the second right rail segment. The left rail includes a third left rail segment and a fourth left rail segment. The third left rail segment is supported by the first structure and disposed on the first side in the path direction relative to the first left rail segment. The fourth left rail segment is supported by the second structure and disposed on the second side in the path direction relative to the second right rail segment. The first right rail segment and the third right rail segment are connected by a right first connection assembly that allows relative swinging of the first right rail segment and the third right rail segment about an axis extending in a direction perpendicular to the path direction. The second right rail segment and the fourth right rail segment are connected by a right second connection assembly that allows relative swinging of the second right rail segment and the fourth right rail segment about an axis extending in the direction perpendicular to the path direction. The first left rail segment and the third left rail segment are connected by a left first connection assembly that allows relative swinging of the first left rail segment and the third left rail segment about an axis extending in the direction perpendicular to the path direction. The second left rail segment and the fourth left rail segment are connected by a left second connection assembly that allows relative swinging of the second left rail segment and the fourth left rail segment about an axis extending in the direction perpendicular to the path direction.

In this structure, the first right rail segment and the second right rail segment are coupled by the right linear guide assembly, and the first left rail segment and the second left rail segment are coupled by the left linear guide assembly. This structure restricts displacement between the first right rail segment and the second right rail segment in the lateral or vertical direction while allowing the first right rail segment and the second right rail segment to move toward and away from each other, and restricts displacement between the first left rail segment and the second left rail segment in the lateral or vertical direction while allowing the first left rail segment and the second left rail segment to move toward and away from each other when the first structure and the second structure vibrate differently. This structure can thus easily maintain the state in which the transport vehicle travels continuously. The first right rail segment and the third right rail segment are connected by the right first connection assembly, the second right rail segment and the fourth right rail segment are connected by the right second connection assembly, the first left rail segment and the third left rail segment are connected by the left first connection assembly, and the second left rail segment and the fourth left rail segment are connected by the left second connection assembly. This structure can thus reduce the likelihood of the breakage of the travel rails while maintaining the state in which the first right rail segment and the second right rail segment aligned linearly and the first left rail segment and the second left rail segment aligned linearly although the first structure and the second structure vibrate differently.

In one aspect, the transport facility further includes an auxiliary rail separation section between the first auxiliary section and the second auxiliary section. The auxiliary rail separation section is free of the auxiliary rail. The auxiliary rail includes at least one of a first slope section or a second slope section. The first slope section is continuous with the first auxiliary section on a side toward the auxiliary rail separation section in the path direction. The first slope section slopes toward the first side in the swing direction at positions closer to the auxiliary rail separation section. The second slope section is continuous with the second auxiliary section on a side toward the auxiliary rail separation section in the path direction. The second slope section slopes toward the second side in the swing direction at positions closer to the auxiliary rail separation section.

This structure allows smooth change when the auxiliary unit in contact with the auxiliary rail on one side changes to come in contact with the auxiliary rail on the other side.

In one aspect, the transport facility further includes a first right support assembly and a first left support assembly supported by the first structure. The first right support assembly includes a first urging assembly supporting the first right rail segment to allow movement of the first right rail segment in a vertical direction and a lateral direction relative to the first structure. The first urging assembly urges the first right rail segment toward a reference position in the vertical direction and a reference position in the lateral direction. The lateral direction is perpendicular to the path direction when viewed in the vertical direction. The first left support assembly includes a second urging assembly supporting the first left rail segment to allow movement of the first left rail segment in the vertical direction and the lateral direction relative to the first structure. The second urging assembly urges the first left right rail segment toward a reference position in the vertical direction and a reference position in the lateral direction.

This structure reduces vibrations resulting from traveling of the transport vehicle in the first right rail segment spaced from the second right rail segment and in the first left rail segment spaced from the second left rail segment. The vibrations transmitted to the first right rail segment and the first left rail segment can be reduced when the first structure vibrates, easily avoiding the breakage of the first right rail segment and the first left rail segment.

The transport facility according to one or more embodiments of the present disclosure produces at least one of the effects described above.

What is claimed is:

1. A transport facility, comprising:
a transport vehicle comprising a right wheel and a left wheel to travel along a travel path; and
travel rails comprising a right rail on which the right wheel rolls and a left rail on which the left wheel rolls, and
wherein:
the travel rails extend across a first structure and a second structure, the first structure and the second structure being configured to vibrate differently,
the right rail comprises:
a first right rail segment supported by the first structure, and
a second right rail segment supported by the second structure and spaced from the first right rail segment in a path direction being a direction parallel to the travel path,
the left rail comprises:
a first left rail segment supported by the first structure, and
a second left rail segment supported by the second structure and spaced from the first left rail segment in the path direction,
the transport vehicle comprises an auxiliary unit at a position different from a position of the right wheel and a position of the left wheel,
the travel rails comprises an auxiliary rail in a section of the travel path at a position corresponding to the auxiliary unit,
the auxiliary rail comprises:
a first auxiliary section in which the auxiliary unit comes in contact with and is guided along the auxiliary rail on a second side in a swing direction while the right wheel is in a right separation state in which the right wheel is passing through a right separation section, the swing direction being a direction in which the transport vehicle along the travel path swings about a swing axis, the second side in the swing direction being a side on which the left wheel is lowered in the swing direction relative to the right wheel, the right separation section being a section between the first right rail segment and the second right rail segment in the path direction, and
a second auxiliary section in which the auxiliary unit comes in contact with and is guided along the auxiliary rail on a first side in the swing direction while the left wheel is in a left separation state in which the left wheel is passing through a left separation section, the first side in the swing direction being a side on which the right wheel is lowered in the swing direction relative to the left wheel, the left separation section being a section between the first left rail segment and the second left rail segment in the path direction, and
the right separation section and the left separation section are arranged to cause the right separation state and the left separation state to occur at different times.

2. The transport facility according to claim 1, wherein:
the auxiliary rail is supported by the first structure or the second structure, or the auxiliary rail includes a section supported by the first structure and a section supported by the second structure separated from each other.

3. The transport facility according to claim 1, further comprising:
a right linear guide assembly configured to allow relative movement of the first right rail segment and the second right rail segment in the path direction and restrict relative movement of the first right rail segment and the second right rail segment in a direction perpendicular to the path direction; and
a left linear guide assembly configured to allow relative movement of the first left rail segment and the second left rail segment in the path direction and restrict relative movement of the first left rail segment and the second left rail segment in the direction perpendicular to the path direction, and
wherein:
the right rail has the first right rail segment disposed on a first side in the path direction relative to the second right rail segment,
the right rail comprises:
a third right rail segment supported by the first structure and disposed on the first side in the path direction relative to the first right rail segment, and
a fourth right rail segment supported by the second structure and disposed on a second side in the path direction relative to the second right rail segment,
the left rail has the first left rail segment disposed on the first side in the path direction relative to the second right rail segment,
the left rail comprises:
a third left rail segment supported by the first structure and disposed on the first side in the path direction relative to the first left rail segment, and
a fourth left rail segment supported by the second structure and disposed on the second side in the path direction relative to the second right rail segment,
the first right rail segment and the third right rail segment are connected by a right first connection assembly configured to allow relative swinging of the first right rail segment and the third right rail segment about an axis extending in a direction perpendicular to the path direction,
the second right rail segment and the fourth right rail segment are connected by a right second connection assembly configured to allow relative swinging of the second right rail segment and the fourth right rail segment about an axis extending in the direction perpendicular to the path direction,
the first left rail segment and the third left rail segment are connected by a left first connection assembly configured to allow relative swinging of the first left rail segment and the third left rail segment about an axis extending in the direction perpendicular to the path direction, and
the second left rail segment and the fourth left rail segment are connected by a left second connection assembly configured to allow relative swinging of the second left rail segment and the fourth left rail segment about an axis extending in the direction perpendicular to the path direction.

4. The transport facility according to claim 1, further comprising:
an auxiliary rail separation section between the first auxiliary section and the second auxiliary section, the auxiliary rail separation section being free of the auxiliary rail,
wherein the auxiliary rail comprises at least one of:
a first slope section continuous with the first auxiliary section on a side toward the auxiliary rail separation section in the path direction, the first slope section sloping toward the first side in the swing direction at positions closer to the auxiliary rail separation section, or
a second slope section continuous with the second auxiliary section on a side toward the auxiliary rail separation section in the path direction, the second slope section sloping toward the second side in the swing direction at positions closer to the auxiliary rail separation section.

5. The transport facility according to claim 1, further comprising:
a first right support assembly and a first left support assembly supported by the first structure,
wherein the first right support assembly comprises a first urging assembly supporting the first right rail segment to allow movement of the first right rail segment in a vertical direction and a lateral direction relative to the first structure, the first urging assembly urges the first right rail segment toward a reference position in the vertical direction and a reference position in the lateral direction, and the lateral direction is perpendicular to the path direction when viewed in the vertical direction, and
wherein the first left support assembly comprises a second urging assembly supporting the first left rail segment to allow movement of the first left rail segment in the vertical direction and the lateral direction relative to the first structure, and the second urging assembly urges the first left right rail segment toward a reference position in the vertical direction and a reference position in the lateral direction.
